(19) United States
(12) Patent Application Publication
(10) Pub. No.: US 2016/0098953 A1
(43) Pub. Date: Apr. 7, 2016

(54) DISPLAY PANEL AND ELECTRONIC DEVICE WITH ELECTROSTATIC DISCHARGE PROTECTION FUNCTION

(71) Applicant: SHENZHEN CHINA STAR OPTOELECTRONICS TECHNOLOGY CO., LTD., Shenzhen, guangdong (CN)

(72) Inventors: Kai-Yuan KO, Shenzhen, Guangdong (CN); Xiaoxiang HE, Shenzhen, Guangdong (CN)

(73) Assignee: SHENZHEN CHINA STAR OPTOELECTRONICS TECHNOLOGY CO., LTD., Shenzhen,Guangdong (CN)

(21) Appl. No.: 14/111,799

(22) PCT Filed: Jul. 5, 2013
(86) PCT No.: PCT/CN2013/078865

§ 371 Date: Oct. 15, 2013

(30) Foreign Application Priority Data
Jun. 28, 2013 (CN) 201310269958.6

(51) Int. Cl. G09G 3/32; H01L 27/32; H01L 27/02

(52) U.S. Cl. CPC G09G 3/3225; H01L 27/0296; H01L 27/3276; G09G 2330/04

(57) ABSTRACT

A display panel with an electrostatic discharge (ESD) protection function, includes a organic light emitting diode (OLED) light area, a scan driving circuit, and a data driving circuit. Therein, the OLED light area includes a number of pixel regions which are arranged in array mode. The scan driving circuit and the OLED light area are connected to each other via a number of scan lines which are fanned out. The data driving circuit and the OLED light area are connected to each other via a number of data lines which are fanned out. Therein, each data line is connected to one voltage point via a first OLED, each scan line is connected to one voltage point via a second OLED.

### TECHNICAL FIELD OF THE INVENTION

The present invention relates to display panels, and more particularly, to a display panel and an electronic device with an electrostatic discharge protection function.

### BACKGROUND OF THE INVENTION

Nowadays, active-matrix organic light-emitting diode (AMOLED) panels with characters of fast response time, high contrast, larger viewing angle, and the like with respect to traditional liquid crystal panels. Therefore, the AMOLED panels are taken as choice for display devices gradually. Usually, in order to prevent the AMOLED panel from damage caused by the influence of the electrostatic discharge (ESD), the AMOLED panel usual includes ESD protection circuit. Usually, the common AMOLED panel uses metal oxide semiconductor field-effect transistor (MOS TFT) as the ESD protection circuit. It is need to prepare a little of MOS FETs specially, it is not facilitated for batch production and brings high cost and complex manufacturing process.

### SUMMARY OF THE INVENTION

The present invention provides a display panel and an electronic device with an electrostatic discharge protection function, capable of reducing the cost and simplifying the manufacturing process.

A display panel with an electrostatic discharge (ESD) protection function comprising a organic light emitting diode (OLED) light area, a scan driving circuit, and a data driving circuit; wherein, the OLED light area comprises a plurality of pixel regions which are arranged in array mode, the scan driving circuit and the OLED light area are connected to each other via a plurality of scan lines which are fanned out; the data driving circuit and the OLED light area are connected to each other via a plurality of data lines which are fanned out; wherein, each data line is connected to one voltage point via a first OLED, each scan line is connected to one voltage point via a second OLED.

Therein, each pixel region comprises a third OLED, a switch transistor, and a driving transistor; a gate of the switch transistor of each pixel region is connected to the scan line, a source of the switch transistor is connected to the data line, a drain of the switch transistor is connected to a gate of the driving transistor; a source of the driving transistor is connected to a positive voltage, a drain of the driving transistor is connected to anode of the third OLED, a cathode of the third OLED is grounded.

Therein, the data line is connected to a zero voltage via the first OLED which is reverse connected; and the scan line are connected to the zero voltage respectively via the second OLED which is reverse connected.

Therein, the data line is connected to the positive voltage via the first OLED which is forward connected, and the scan line is connected to the positive voltage via the second OLED which is forward connected.

Therein, the data line is connected to the zero voltage to connect ground via one first OLED which is reverse connected and is further connected to the positive voltage via another first OLED which is forward connected; the scan line is connected to the zero voltage to connect ground via one second OLED which is reverse connected and is further connected to the positive voltage via another second OLED which is forward connected.

Therein, the display panel is an active-matrix organic light-emitting diode display panel.

An electronic device comprising a display panel, wherein the display panel comprises a organic light emitting diode (OLED) light area, a scan driving circuit, and a data driving circuit; the OLED light area comprises a plurality of pixel regions which are arranged in array mode, the scan driving circuit and the OLED light area are connected to each other via a plurality of scan lines which are fanned out; the data driving circuit and the OLED light area are connected to each other via a plurality of data lines which are fanned out; wherein, each data line is connected to one voltage point via a first OLED, each scan line is connected to one voltage point via a second OLED.

Therein, each pixel region comprises a third OLED, a switch transistor, and a driving transistor; a gate of the switch transistor of each pixel region is connected to the scan line, a source of the switch transistor is connected to the data line, a drain of the switch transistor is connected to a gate of the driving transistor; a source of the driving transistor is connected to a positive voltage, a drain of the driving transistor is connected to anode of the third OLED, a cathode of the third OLED is grounded.

Therein, the data line is connected to a zero voltage via the first OLED which is reverse connected; and the scan line are connected to the zero voltage respectively via the second OLED which is reverse connected.

Therein, the data line is connected to the positive voltage via the first OLED which is forward connected, and the scan line is connected to the positive voltage via the second OLED which is forward connected.

Therein, the data line is connected to the zero voltage to connect ground via one first OLED which is reverse connected and is further connected to the positive voltage via another first OLED which is forward connected; the scan line is connected to the zero voltage to connect ground via one second OLED which is reverse connected and is further connected to the positive voltage via another second OLED which is forward connected.

Therein, the display panel is an active-matrix organic light-emitting diode display panel.

Therein, the electronic device is a mobile phone, a tablet computer, a display, or a television.

The display panel and the electronic device of the present invention, capable of reducing the cost and simplifying the manufacturing process.

### BRIEF DESCRIPTION OF THE DRAWINGS

FIG. 1 is a schematic diagram of a display panel with an electrostatic discharge (ESD) protection function of an embodiment;

FIG. 2 is a schematic diagram illustrating a connection relationship of an organic light emitting diode taken as a ESD protection element of a display panel with a ESD protection function of a first embodiment;

FIG. 3 is a schematic diagram illustrating a connection relationship of an organic light emitting diode taken as a ESD protection element of a display panel with a ESD protection function of a second embodiment;

FIG. 4 is a schematic diagram illustrating a connection relationship of an organic light emitting diode taken as a ESD protection element of a display panel with a ESD protection function of a third embodiment; and

FIG. 5 is a block diagram of an electronic device of an embodiment.

### DETAILED DESCRIPTION OF THE PREFERRED EMBODIMENTS

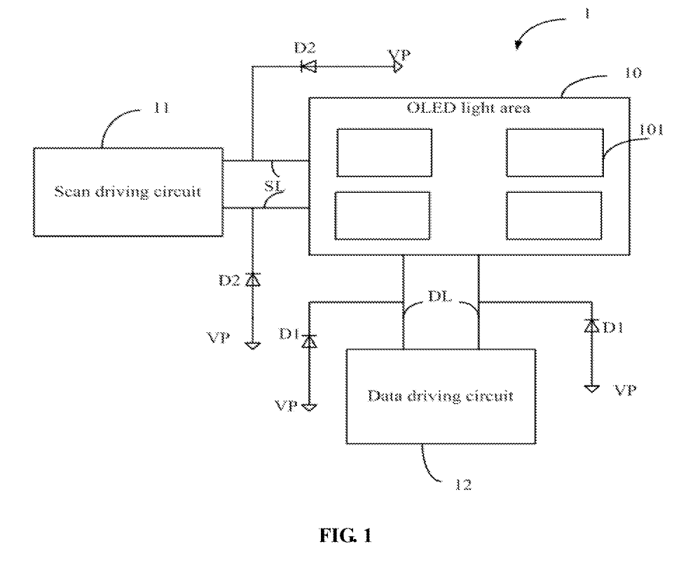

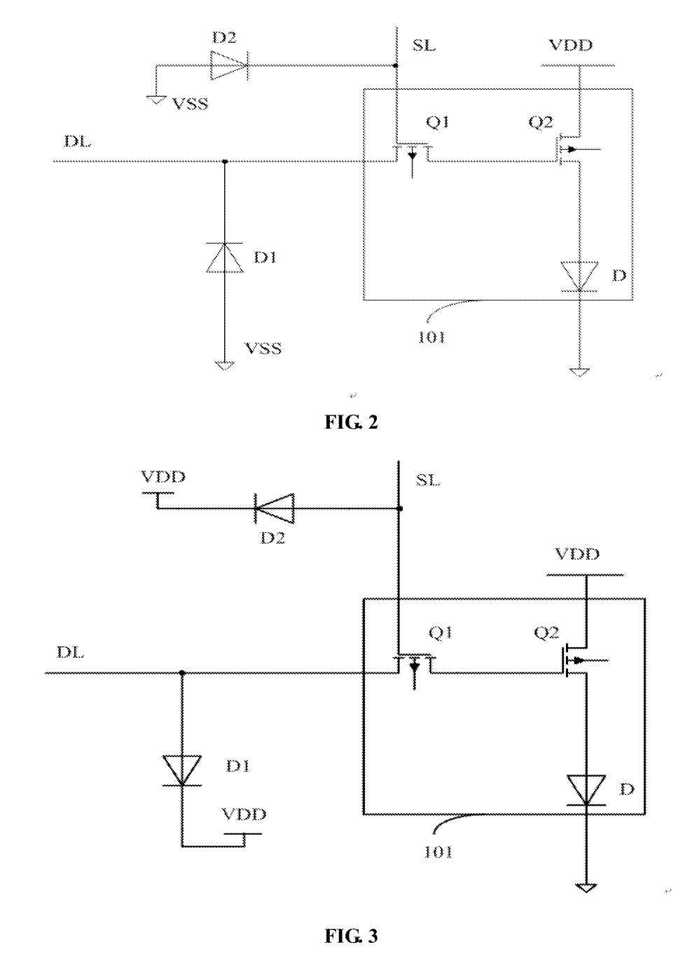

Referring to FIGS. 1 and 2 together, FIG. 1 is a schematic diagram of a display panel 1 with an electrostatic discharge (ESD) protection function of an embodiment. FIG. 2 is a schematic diagram illustrating a connection relationship of an organic light emitting diode taken as an ESD protection element of a display panel with an ESD protection function of an embodiment. The display panel 1 includes an organic light emitting diode (OLED) light area 10, a scan driving circuit 11, and a data driving circuit 12.

The OLED light area 10 includes a number of pixel regions 101 which are arranged in array mode.

The scan driving circuit 11 and the OLED light area 10 are connected to each other via a number of scan lines SL which are fanned out. The data driving circuit 12 and the OLED light area 10 are connected to each other via a number of data lines DL which are fanned out.

As shown in FIG. 1, each data line DL is connected to one voltage point VP via a OLED D1. Each scan line SL is connected to one voltage point VP via a OLED D2. The OLED D1 and the OLED D2 are used as ESD protection elements. Therein, the OLED D1 or the OLED D2 is reverse breakdown when electrostatic charges of the data line DL or the scan line SL are accumulated to a certain value, thus transmitting the electrostatic charges to the voltage point VP and preventing inner array of the display panel 1 from damage.

As shown in FIG. 2, each pixel region 101 includes a OLED D, a switch transistor Q1, and a driving transistor Q2. A gate of the switch transistor Q1 is connected to the scan line SL, a source of the switch transistor Q1 is connected to the data line DL, a drain of the switch transistor Q1 is connected to a gate of the driving transistor Q2. A source of the driving transistor Q2 is connected to a positive voltage VDD, a drain of the driving transistor Q2 is connected to anode of the OLED D. A cathode of the OLED D is grounded.

When a gating signal is applied to the scan line SL, the switch transistor Q1 connected to the scan line SL is turned on, a data signal of the data line DL is applied to the gate of the driving transistor Q2 via the switch transistor Q1 which is turned on. The driving transistor Q2 is turned on accordingly, the positive voltage VDD is applied to the OLED D via the driving transistor Q2 which is turned on and then drives the OLED D to emit light.

As shown in FIG. 2, in the first embodiment, the data line DL and the scan line SL are connected to a zero voltage VSS respectively via the OLED D1 and the OLED D2 which are reverse connected. Namely, a cathode of the OLED D1 is connected to the data line DL, an anode of the OLED D1 is grounded; a cathode of the OLED D2 is connected to the scan line SL, an anode of the OLED D2 is grounded. Therefore, when the ESD is happened, namely the electrostatic charges of the data line DL or the scan line SL are accumulated to the certain value, the corresponding OLED D1 or OLED D2 is reverse breakdown and transmits the electrostatic charges to ground. Thus preventing the inner array of the display panel 1 from damage.

As shown in FIG. 3, in a second embodiment, the data line DL and the scan line SL are connected to the positive voltage VDD respectively via the OLED D1 and the OLED D2 which are forward connected. Namely, an anode of the OLED D1 is connected to the data line DL, a cathode of the OLED D1 is grounded; an anode of the OLED D2 is connected to the scan line SL, a cathode of the OLED D2 is grounded. Therefore, when the electrostatic charges of the data line DL or the scan line SL are accumulated to the certain value, the corresponding OLED D1 or OLED D2 is also reverse breakdown and transmits the electrostatic charges to ground.

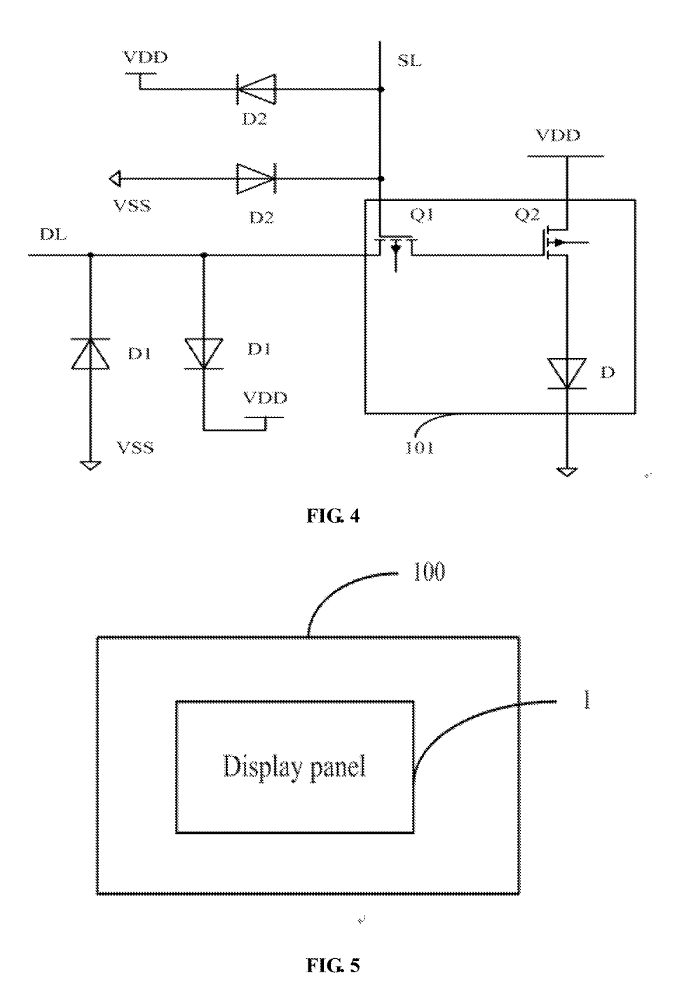

As shown in FIG. 4, in a third embodiment, each data line DL is connected to the zero voltage VSS to connect ground via one OLED D1 which is reverse connected and is also connected to the positive voltage VDD via another OLED D1 which is forward connected. The scan line SL is connected to the zero voltage VSS to connect ground via one OLED D2 which is reverse connected and is also connected to the positive voltage VDD via another OLED D2 which is forward connected. Therefore, when the electrostatic charges of the data line DL are accumulated to the certain value, the two OLEDs D1 connected to the data line DL are reverse breakdown and respectively transmits the electrostatic charges to ground or the positive voltage VDD. When the electrostatic charges of the scan line SL are accumulated to the certain value, the two OLEDs D2 connected to the scan line SL are reverse breakdown and respectively transmits the electrostatic charges to ground or the positive voltage VDD

In the embodiment, the display panel 1 is an active-matrix organic light-emitting diode display panel.

Therefore, in the embodiment, by using the OLEDs as ESD protection elements, the ESD protection elements can be produced or buy with the OLEDs used in the display panel 1. It is no need to prepare a few of particular MOS FETs, which decreases the cost and simplifies the manufacturing process.

Referring to FIG. 5, an electronic device 100 includes the display panel 1 is illustrated. The electronic device 100 includes the display panel 1 and other necessary elements. The electronic device 100 can be a mobile phone, a tablet computer, a display, or a television, and the like.

The present invention may be embodied in other forms without departing from the spirit or novel characteristics thereof. The embodiments disclosed in this application are to be considered in all respects as illustrative and not limitative. The scope of the invention is indicated by the appended claims rather than by the foregoing description; and all changes which come within the meaning and range of equivalency of the claims are intended to be embraced therein.

What is claimed is:

1. A display panel with an electrostatic discharge (ESD) protection function, comprising a organic light emitting diode (OLED) light area, a scan driving circuit, and a data driving circuit; wherein, the OLED light area comprises a plurality of pixel regions which are arranged in array mode, the scan driving circuit and the OLED light area are connected to each other via a plurality of scan lines which are fanned out; the data driving circuit and the OLED light area are connected to each other via a plurality of data lines which are fanned out; wherein, each data line is connected to one voltage point via a first OLED, each scan line is connected to one voltage point via a second OLED.

2. The display panel of claim 1, wherein each pixel region comprises a third OLED, a switch transistor, and a driving transistor; a gate of the switch transistor of each pixel region is connected to the scan line, a source of the switch transistor is connected to the data line, a drain of the switch transistor is connected to a gate of the driving transistor; a source of the driving transistor is connected to a positive voltage, a drain of the driving transistor is connected to anode of the third OLED, a cathode of the third OLED is grounded.

3. The display panel of claim 2, wherein the data line is connected to a zero voltage via the first OLED which is reverse connected; and the scan line are connected to the zero voltage respectively via the second OLED which is reverse connected.

4. The display panel of claim 2, wherein the data line is connected to the positive voltage via the first OLED which is forward connected, and the scan line is connected to the positive voltage via the second OLED which is forward connected.

5. The display panel of claim 2, wherein the data line is connected to the zero voltage to connect ground via one first OLED which is reverse connected and is further connected to the positive voltage via another first OLED which is forward connected; the scan line is connected to the zero voltage to connect ground via one second OLED which is reverse connected and is further connected to the positive voltage via another second OLED which is forward connected.

6. The display panel of claim 2, wherein the display panel is an active-matrix organic light-emitting diode display panel.

7. An electronic device, comprising a display panel, wherein the display panel comprises a organic light emitting diode (OLED) light area, a scan driving circuit, and a data driving circuit; the OLED light area comprises a plurality of pixel regions which are arranged in array mode, the scan driving circuit and the OLED light area are connected to each other via a plurality of scan lines which are fanned out; the data driving circuit and the OLED light area are connected to each other via a plurality of data lines which are fanned out; wherein, each data line is connected to one voltage point via a first OLED, each scan line is connected to one voltage point via a second OLED.

8. The electronic device of claim 7, wherein each pixel region comprises a third OLED, a switch transistor, and a driving transistor; a gate of the switch transistor of each pixel region is connected to the scan line, a source of the switch transistor is connected to the data line, a drain of the switch transistor is connected to a gate of the driving transistor; a source of the driving transistor is connected to a positive voltage, a drain of the driving transistor is connected to anode of the third OLED, a cathode of the third OLED is grounded.

9. The electronic device of claim 8, wherein the data line is connected to a zero voltage via the first OLED which is reverse connected; and the scan line are connected to the zero voltage respectively via the second OLED which is reverse connected.

10. The electronic device of claim 8, wherein the data line is connected to the positive voltage via the first OLED which is forward connected, and the scan line is connected to the positive voltage via the second OLED which is forward connected.

11. The electronic device of claim 8, wherein the data line is connected to the zero voltage to connect ground via one first OLED which is reverse connected and is further connected to the positive voltage via another first OLED which is forward connected; the scan line is connected to the zero voltage to connect ground via one second OLED which is reverse connected and is further connected to the positive voltage via another second OLED which is forward connected.

12. The electronic device of claim 8, wherein the display panel is an active-matrix organic light-emitting diode display panel.

13. The electronic device of claim 8, wherein the electronic device is a mobile phone, a tablet computer, a display, or a television.
